(19) United States
(12) Patent Application Publication
(10) Pub. No.: US 2021/0313554 A1
(43) Pub. Date: Oct. 7, 2021

(54) LAMINATE-TYPE ELECTRICAL STORAGE DEVICE AND METHOD OF INSPECTING SHORT-CIRCUITING OF THE SAME

(71) Applicant: TOYOTA JIDOSHA KABUSHIKI KAISHA, Toyota-shi (JP)

(72) Inventor: Hirokazu KAWAOKA, Nisshin-shi (JP)

(73) Assignee: TOYOTA JIDOSHA KABUSHIKI KAISHA, Toyota-shi (JP)

(21) Appl. No.: 17/176,267

(22) Filed: Feb. 16, 2021

(30) Foreign Application Priority Data
Apr. 2, 2020 (JP) 2020-066777

(51) Int. Cl. H01M 4/13; H01M 4/04

(52) U.S. Cl. CPC H01M 4/13; H01M 4/04

(57) ABSTRACT

An exterior body envelops an electrode lamination portion by a laminate film or a plurality of laminate films. The exterior body has a mating surface obtained by superimposing portions of an inside surface of the laminate film or inside surfaces of the laminate films on each other and heat-sealing a thermoplastic resin layer to the inside surface or each of the inside surfaces, around the electrode lamination portion. A positive electrode collection tab and a negative electrode collection tab stick out from the mating surface beyond the laminate film or the laminate films. The exterior body has a metal exposure portion for inspecting a potential of a metal sheet of the laminate film or each of the laminate films, at least partially outside the mating surface around the electrode lamination portion.

### CROSS-REFERENCE TO RELATED APPLICATION

This application claims priority to Japanese Patent Application No. 2020-066777 filed on Apr. 2, 2020, incorporated herein by reference in its entirety.

### BACKGROUND

### 1. Technical Field

The disclosure relates to a laminate-type electrical storage device and a method of inspecting the short-circuiting of the same.

### 2. Description of Related Art

In Japanese Unexamined Patent Application Publication No. 2016-31829 (JP 2016-31829 A), there is disclosed an electrochemical device having, partially on an outer surface of a laminate exterior material, an energization terminal portion from which a heat-resistant resin layer has been removed. In JP 2016-31829 A, this electrochemical device measures an electrical resistance value between the device and a tab lead drawn out from the laminate exterior material, and the insulation properties between an exterior body and a device body is inspected based on the measured electrical resistance value.

In WO 2014/147808, there is disclosed a method of inspecting a film-sheathed battery. In this method, an exterior body is pressurized from the outside along a lamination direction of electric power generation elements, and an insulation failure is inspected between a terminal and a metal layer with the exterior body thus pressurized.

In WO 2011/040446, there is disclosed a process of applying an impulse voltage to a marginal part between a metal terminal and a metal foil layer, and measuring a waveform of a voltage applied to a capacitance element between the metal terminal and the metal foil layer.

### SUMMARY

By the way, the inventor intends to propose a structure capable of easily realizing an inspection of the short-circuiting between an exterior body made from laminate films, and a collection tab extracted from a mating surface of the laminate films, as to a so-called laminate-type electrical storage device.

A laminate-type electrical storage device disclosed in this specification is equipped with an electrode body, and an exterior body equipped with one or a plurality of laminate films. The electrode body has an electrode lamination portion, a positive electrode collection tab, and a negative electrode collection tab. The laminate film or each of the laminate films has a metal sheet, an insulating resin layer that covers an outside surface of the metal sheet, and a thermoplastic resin layer that covers an inside surface of the metal sheet. The exterior body envelops the electrode lamination portion by the laminate film or the laminate films. The exterior body has a mating surface obtained by superimposing portions of an inside surface of the laminate film or inside surfaces of the laminate films on each other and heat-sealing the thermoplastic resin layer to the inside surface or each of the inside surfaces, around the electrode lamination portion. The positive electrode collection tab and the negative electrode collection tab stick out from the mating surface beyond the laminate film or the laminate films. The exterior body has a metal exposure portion for inspecting a potential of the metal sheet of the laminate film or each of the laminate films, at least partially outside the mating surface around the electrode lamination portion. With this laminate-type electrical storage device, the metal exposure portion for inspecting the potential of the metal sheet of the laminate film or each of the laminate films exists at least partially outside the mating surface around the electrode lamination portion. Therefore, the short-circuiting of the laminate film or the laminate films can be easily inspected.

The laminate film or each of the laminate films may have a region extending outward beyond the mating surface around the electrode lamination portion. The metal exposure portion may have a part where the inside surface of the metal sheet is exposed, at least partially in the region extending outward beyond the mating surface.

The laminate-type electrical storage device may further have a metal member that is sandwiched between portions of the laminate film or between the laminate films, that is electrically connected to the metal sheet of the laminate film or each of the laminate films, and that is exposed from the laminate film or each of the laminate films, on the mating surface of the laminate film or the laminate films.

The exterior body may be constituted of two laminate films that cover the electrode lamination portion in a sandwiching manner, and may have a mating surface obtained by fusing the thermoplastic resin layers of the two laminate films to each other, along a periphery of the electrode lamination portion.

A method of inspecting short-circuiting of a laminate-type electrical storage device may include a process of preparing the foregoing laminate-type electrical storage device, and a process of placing a first probe against the metal exposure portion of the laminate-type electrical storage device and placing a second probe against the positive electrode collection tab or the negative electrode collection tab.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a schematic view showing one of the embodiments of a laminate-type electrical storage device 10 disclosed in this specification;

FIG. 2 is a schematic view schematically showing a cross-section taken along a line II-II;

FIG. 3 is a schematic view showing a laminate-type electrical storage device 10A according to another one of the embodiments;

FIG. 4 is a schematic view showing a laminate-type electrical storage device 10B according to still another one of the embodiments; and

FIG. 5 is a schematic view showing a laminate-type electrical storage device 10C according to still another one of the embodiments.

### DETAILED DESCRIPTION OF EMBODIMENTS

One of the embodiments of a laminate-type electrical storage device disclosed in this specification will be described hereinafter. The embodiments described in this specification are obviously not intended to limit the disclosure in particular. The disclosure is not limited to the embodiments described in this specification unless otherwise specified.

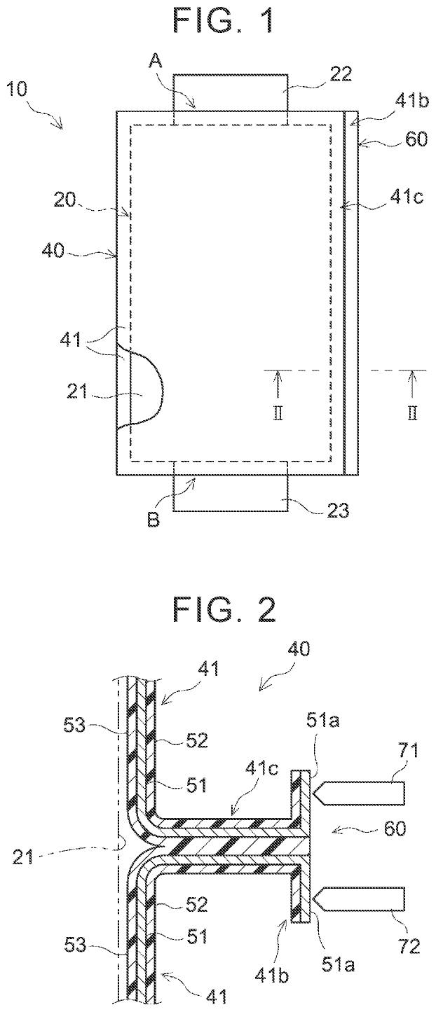

FIG. 1 is a schematic view showing one of the embodiments of a laminate-type electrical storage device 10 disclosed in this specification. In FIG. 1, laminate films 41 are depicted in a partially broken state. FIG. 2 is a schematic view schematically showing a cross-section taken along a line II-II.

In the present specification, “the laminate-type electrical storage device” refers to an electrical storage device with a laminate film used as an exterior material. “The electrical storage device” refers to a device that can be charged with electric power and that can discharge electric power therefrom. In addition to a battery generally referred to as a lithium-ion battery, a lithium secondary battery, or the like, the electrical storage device encompasses a lithium polymer battery, a lithium-ion capacitor, and the like. The secondary battery generally refers to a battery that can be repeatedly charged with electric power and that can repeatedly discharge electric power therefrom as electric charge carriers move between a positive electrode and a negative electrode. An electrolytic solution or a solid electrolyte may be used as the electrical storage device. For example, the secondary battery may be a secondary battery using a so-called liquid-type electrolytic solution, or a so-called all-solid battery using a solid electrolyte.

The laminate-type electrical storage device 10 is equipped with an electrode body 20 and an exterior body 40. The electrode body 20 is equipped with an electrode lamination portion 21, a positive electrode collection tab 22, and a negative electrode collection tab 23.

In this case, the electrode lamination portion 21 is structured to serve as an electric power generation element of the laminate-type electrical storage device 10. The electrode lamination portion 21 is configured such that, for example, a positive electrode sheet and a negative electrode sheet are laminated on each other while facing each other via a separator. The positive electrode sheet is equipped with a positive electrode collector, and a positive electrode active material layer formed on the positive electrode collector and containing positive electrode active material particles. The negative electrode sheet is equipped with a negative electrode collector, and a negative electrode active material layer formed on the negative electrode collector and containing negative electrode active material particles. Incidentally, the structure of the electrode lamination portion 21 differs depending on the type of the electrical storage device such as the lithium-ion secondary battery, the lithium polymer battery, or the lithium-ion capacitor. The structure of the electrode lamination portion 21 can be appropriately changed unless otherwise specified. In this case, the electrode lamination portion 21 is not depicted in detail.

The positive electrode collection tab 22 is electrically connected to the positive electrode collector of the electrode lamination portion 21, and extends from the electrode lamination portion 21. The negative electrode collection tab 23 is electrically connected to the negative electrode collector of the electrode lamination portion 21, and extends from the electrode lamination portion 21. In this embodiment, the electrode lamination portion 21 is substantially rectangular, and the positive electrode collection tab 22 is provided on one side of the electrode lamination portion 21. The negative electrode collection tab 23 is provided on the other side of the electrode lamination portion 21, namely, opposite the side where the positive electrode collection tab 22 is provided. Thus, the positive electrode collection tab 22 and the negative electrode collection tab 23 extend in opposite directions from the electrode lamination portion 21. Incidentally, the positions where the positive electrode collection tab 22 and the negative electrode collection tab 23 are provided on the electrode lamination portion 21, the directions in which the positive electrode collection tab 22 and the negative electrode collection tab 23 extend from the electrode lamination portion 21, and the like can also be appropriately changed unless otherwise specified.

The exterior body 40 is equipped with one or a plurality of laminate films 41. The laminate film 41 or each of the laminate films 41 has a metal sheet 51, an insulating resin layer 52 that covers an outside surface of the metal sheet 51, and a thermoplastic resin layer 53 that covers an inside surface 51a of the metal sheet 51.

It should be noted herein that the metal sheet 51 plays the role of providing the laminate film 41 or each of the laminate films 41 with gas barrier properties for preventing oxygen, moisture, and electrolytic solution from entering thereinto. The metal sheet 51 may be a thin metal film such as an aluminum foil, a copper foil, a nickel foil, a stainless foil, a clad foil thereof, an annealed foil thereof, or an unannealed foil thereof. Alternatively, the metal sheet 51 may be a metal foil plated with a conductive metal such as nickel, tin, copper, or chrome. Besides, a chemical conversion coating film may be formed on the metal sheet 51 as a substrate treatment. The chemical conversion coating film is a film that is formed by subjecting the surface of the metal sheet 51 to a chemical conversion treatment. As the chemical conversion treatment, it is possible to mention, for example, a chromate treatment, or a non-chrome-type chemical conversion treatment using a zirconium compound.

The insulating resin layer 52 is a layer outside the laminate film 41 or each of the laminate films 41. The insulating resin layer 52 has insulating properties, and has such a melting point as not to melt when the thermoplastic resin layer 53 is melted and bonded thereto. As the resin used for the insulating resin layer 52, it is possible to mention, for example, a resin with a sufficiently higher melting point than the resin used for the thermoplastic resin layer 53, such as polyamide or polyester. A stretched film of these resins can be used as the insulating resin layer 52. Above all, a biaxially-stretched polyamide film, a biaxially-stretched polyester film, or a multi-layer film containing these films can be used from the standpoint of moldability and strength. Furthermore, a multi-layer film obtained by sticking a biaxially-stretched polyamide film and a biaxially-stretched polyester film together may be used. The polyamide film is not limited in particular. However, it is possible to mention, for example, a 6-nylon film, a 6,6-nylon film, or an MXD nylon film as the polyamide film. Besides, it is possible to mention, for example, a biaxially-stretched polybutylene terephthalate (PBT) film or a biaxially-stretched polyethylene terephthalate (PET) film as the biaxially-stretched polyester film.

A lubricating agent and/or solid particles may be blended into the insulating resin layer 52. The sliding properties of the surface of the insulating resin layer 52 are enhanced due to the blending of the lubricating agent and/or the solid particles. The thickness of the insulating resin layer 52 may be, for example, 9 μm to 50 μm. The insulating resin layer 52 may be a single layer, or may be a lamination of multiple layers to enhance strength or the like.

The thermoplastic resin layer 53 is a layer that is formed inside the metal sheet 51. The thermoplastic resin layer 53 desirably exhibits excellent chemical resistance also against corrosivity that is required of an electrical storage device such as a lithium-ion secondary battery. Besides, the thermoplastic resin layer 53 is heat-welded when the inside surface of the laminate film 41 or each of the laminate films 41 is superimposed thereon and bonded thereto, and exhibits heat sealing properties.

From the standpoint of chemical resistance and heat sealing properties, the thermoplastic resin layer 53 preferably consists of polyethylene, polypropylene, an olefinic copolymer, and acidic modified products and ionomers thereof. Besides, an ethylene-vinyl acetate copolymer (EVA), an ethylene-acrylic acid copolymer (EAA), or an ethylene-methacrylic acid copolymer (EMAA) can be exemplified as the olefinic copolymer. Besides, a polyamide film (e.g., 12-nylon) or a polyimide film can also be used. The thermoplastic resin layer 53 may be, for example, a thermoplastic resin unstretched film. The thermoplastic resin unstretched film is not limited in particular, but preferably consists of polyethylene, polypropylene, an olefinic copolymer, and acidic modified products and ionomers thereof, from the standpoint of chemical resistance and heat sealing properties. Besides, an ethylene-vinyl acetate copolymer (EVA), an ethylene-acrylic acid copolymer (EAA), or an ethylene-methacrylic acid copolymer (EMAA) can be exemplified as the olefinic copolymer. Besides, a polyamide film (e.g., 12-nylon) or a polyimide film can also be used. A lubricating agent and/or solid particles may be blended into the thermoplastic resin layer 53 to improve the sliding properties of the surface.

The thickness of the thermoplastic resin layer 53 may be set such that the generation of pinholes can be sufficiently prevented. From this standpoint, the thickness of the thermoplastic resin layer 53 is desirably equal to or larger than 20 μm. Besides, it is desirable to hold the amount of usage of resin small. From this standpoint, the thickness of the thermoplastic resin layer 53 is desirably equal to or smaller than 100 μm, for example, equal to or smaller than 80 μm, and preferably equal to or smaller than 50 μm. The thermoplastic resin layer 53 may be a single layer, or may be constituted of multiple layers. A three-layer film obtained by laminating a random polypropylene film on both surfaces of a block polypropylene film can be exemplified as a multi-layer film.

The laminate film 41 or each of the laminate films 41 envelops the electrode lamination portion 21 of the electrode body 20. The laminate film 41 or each of the laminate films 41 has a mating surface 41c that is obtained by superimposing portions of an inside surface of the laminate film 41 or inside surfaces of the laminate films 41 on each other and bonding the portions of the inside surface or the inside surfaces with thermoplastic resin, around the electrode lamination portion 21. The thermoplastic resin layer 53 of the laminate film 41 or each of the laminate films 41 is welded to the mating surface 41c.

In this embodiment, as a concrete example of the laminate film 41 or each of the laminate films 41, a soft aluminum foil (A8079, A8021, JISH4160 (1994)) is used as the metal sheet 51. The insulating resin layer 52 is a heat-resistant resin layer containing biaxially-stretched nylon (6-nylon). Polyethylene terephthalate is used to bond the metal sheet 51 and the insulating resin layer 52 together. The metal sheet 51 is a mat surface on the side where the insulating resin layer 52 is formed. Modified polypropylene is used as an adhesive to bond the metal sheet 51 and the thermoplastic resin layer 53 together. The metal sheet 51 is a gloss surface on the side where the thermoplastic resin layer 53 is formed. On the mating surface 41c, the thermoplastic resin layers 53 of the two laminate films 41 are superimposed on each other and melted. The thermoplastic resin layers 53 of the two laminate films 41 are welded to each other while being pressed. Therefore, the thermoplastic resin layer 53 after the melting of the mating surface 41c is thinner than the superimposed thermoplastic resin layers 53 of the two laminate films 41.

In the embodiment shown in FIG. 1, the two laminate films 41 are used. The inside surfaces of the two laminate films 41 face each other. The thermoplastic resin layers 53 are formed on the inside surfaces of the two laminate films 41 respectively. The electrode lamination portion 21 of the electrode body 20 is sandwiched between the two laminate films 41, and is enveloped by the two laminate films 41. The positive electrode collection tab 22 and the negative electrode collection tab 23 stick out from between the two laminate films 41 beyond the laminate films 41. Incidentally, in the embodiment shown in FIG. 1, the electrode lamination portion 21 is substantially rectangular. Each of the laminate films 41 is a rectangular sheet that is reasonably larger than the electrode lamination portion 21. The positive electrode collection tab 22 and the negative electrode collection tab 23 extend from opposed short sides of the electrode lamination portion 21 respectively, and stick out from the laminate films 41.

The thermoplastic resin layers 53 of the two laminate films 41 are applied to each other around the electrode lamination portion 21, and are heat-sealed to each other. A surface obtained by applying and heat-sealing the thermoplastic resin layers 53 of the laminate films 41 to each other is referred to as the mating surface 41c. The positive electrode collection tab 22 and the negative electrode collection tab 23 stick out from the mating surface 41c beyond the laminate films.

In regions A and B where the positive electrode collection tab 22 and the negative electrode collection tab 23 stick out from the laminate films 41 respectively, the positive electrode collection tab 22 and the negative electrode collection tab 23 are sandwiched between the laminate films 41, respectively. In the regions A and B, the laminate films 41 are heat-sealed to the positive electrode collection tab 22 and the negative electrode collection tab 23, respectively. In the regions A and B where the positive electrode collection tab 22 and the negative electrode collection tab 23 stick out from the laminate films 41 respectively, the thermoplastic resin layers 53 of the laminate films 41 are superimposed on the positive electrode collection tab 22 and the negative electrode collection tab 23 and heat-sealed thereto respectively, and the airtightness of the laminate-type electrical storage device 10 is thereby ensured.

In the regions A and B where the positive electrode collection tab 22 and the negative electrode collection tab 23 stick out from the laminate films 41 respectively, the laminate films 41 need to be sufficiently heat-sealed to the positive electrode collection tab 22 and the negative electrode collection tab 23 respectively. Thus, the airtightness of the laminate-type electrical storage device 10 is ensured in the regions A and B. On the other hand, if the thermoplastic resin layers 53 melt too much in the regions A and B respectively, the metal sheets 51 of the laminate films 41 come into contact with the positive electrode collection tab 22 and the negative electrode collection tab 23 respectively, and as a result, become conductive therewith respectively. In the laminate-type electrical storage device 10, the laminate films 41 need to be insulated from the electrode body 20. Therefore, the laminate-type electrical storage device in which the laminate films 41 are conductive with the positive electrode collection tab 22 or the negative electrode collection tab 23 is regarded as defective.

The inventor conceives the idea of confirming whether or not short-circuiting has occurred between the laminate films 41 and the positive electrode collection tab 22, and between the laminate films 41 and the negative electrode collection tab 23, in the laminate-type electrical storage device 10. In particular, as shown in FIG. 1, in the embodiment in which the two laminate films 41 cover the electrode lamination portion 21 in a sandwiching manner, the two laminate films 41 may become conductive with the positive electrode collection tab 22 or the negative electrode collection tab 23. Therefore, the short-circuiting with the positive electrode collection tab 22 and the short-circuiting with the negative electrode collection tab 23 need to be confirmed as to each of the two laminate films 41. In this case, for the inspection of short-circuiting, a probe needs to be placed against the metal sheet 51 of each of the two laminate films 41.

In the laminate-type electrical storage device 10 disclosed in this specification, as shown in FIGS. 1 and 2, the laminate films 41 have a metal exposure portion 60 for inspecting potentials of the metal sheets, at least partially outside the mating surface around the electrode lamination portion 21. As shown in FIGS. 1 and 2, the metal sheets 51 of the laminate films 41 may be exposed to the metal exposure portion 60. By placing probes 71 and 72 (see FIG. 2) against the metal exposure portion 60, the potentials of the metal sheets 51 of the two laminate films 41 are detected respectively.

In the embodiment shown in FIG. 1, the laminate films 41 have regions 41b extending further outward from the mating surface 41c around the electrode lamination portion 21, respectively. The metal exposure portion 60 has a part to which the inside surfaces of the metal sheets 51 are exposed, at least partially in the regions 41b extending outward, respectively. In the embodiment shown in FIG. 1, as shown in FIG. 2, the two laminate films 41 extend outward from the mating surface 41c in the metal exposure portion 60. Moreover, outside the mating surface 41c, for example, the thermoplastic resin layer 53 formed on the inside surface of each of the laminate films 41 is desirably melted, and the inside surface 51a of each of the metal sheets 51 is desirably exposed. Moreover, as shown in FIG. 2, the probes 71 and 72 for measuring the potentials of the metal sheets 51 are desirably placed against the inside surfaces 51a of the metal sheets 51 respectively.

As shown in FIG. 2, the inside surfaces 51a of the metal sheets 51 of the two laminate films 41 are exposed to the metal exposure portion 60. Therefore, the potentials of the metal sheets 51 of the two laminate films 41 are detected by placing the probes 71 and 72 against the inside surfaces 51a of the metal sheets 51 of the two laminate films 41 respectively. In this case, it is advisable to place the other probe on the positive electrode collection tab 22 or the negative electrode collection tab 23 (see FIG. 1). Thus, it is possible to confirm the short-circuiting with the positive electrode collection tab 22 and the short-circuiting with the negative electrode collection tab 23, as to each of the two laminate films 41 of the exterior body 40.

Incidentally, as shown in FIG. 2, the thermoplastic resin layers 53 formed on the inside surfaces of the laminate films 41 are depicted in such a manner as to look entirely lost in the metal exposure portion 60. However, the thermoplastic resin layers 53 may not entirely be lost in the metal exposure portion 60. In the metal exposure portion 60, as regards the regions against which the probes 71 and 72 are placed respectively, the thermoplastic resin layers 53 may be vanished by being partially melted, and the metal sheets 51 may be exposed, respectively. Besides, the two laminate films 41 on which the thermoplastic resin layers 53 are not formed in advance may be prepared as to the parts corresponding to the metal exposure portion 60.

In this manner, the laminate-type electrical storage device 10 has parts where the inside surfaces 51a of the metal sheets 51 are exposed respectively, at least partially in the regions 41b of the laminate films 41 extending outward from the mating surface 41c, respectively. Due to this presence of the parts where the inside surfaces 51a of the metal sheets 51 are exposed, the short-circuiting between the laminate films 41 and the positive electrode collection tab 22, and the short-circuiting between the laminate films 41 and the negative electrode collection tab 23 can be easily inspected.

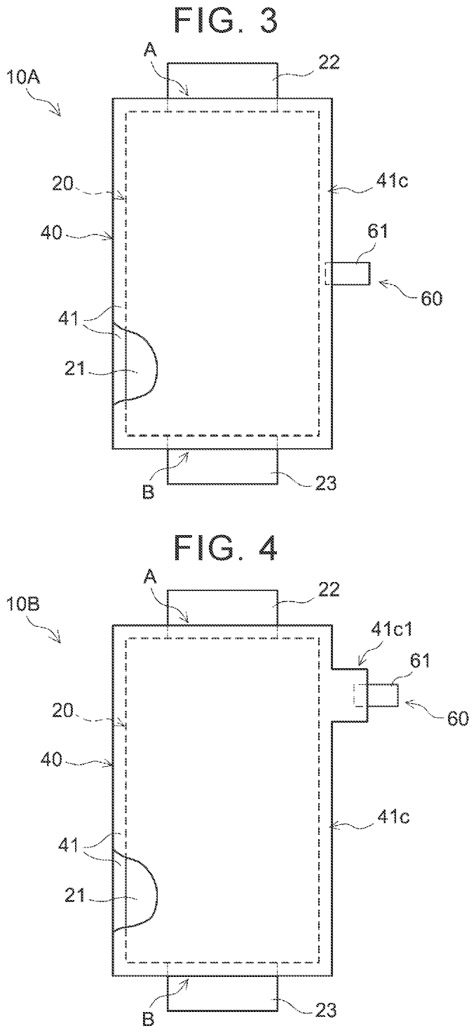

FIG. 3 is a schematic view showing a laminate-type electrical storage device 10A according to another one of the embodiments. In the embodiment shown in FIG. 3, as the metal exposure portion 60, a metal member 61 that is sandwiched between the laminate films 41, that is electrically connected to the metal sheets 51 of the laminate films 41, and that is exposed from the laminate films 41 is provided on the mating surface 41c of the laminate films 41. It should be noted herein that the metal member 61 sandwiched between the laminate films 41 on the mating surface 41c may be, for example, a metal plate made of aluminum, copper, or the like. The metal member 61 sandwiched between the laminate films 41 is desirably conductive with the metal sheets 51 of the laminate films 41.

For example, the thermoplastic resin layers 53 of the laminate films 41 may be partially lost in a part where the metal member 61 is sandwiched between the laminate films 41. Moreover, each of the metal sheets 51 and the metal member 61 are desirably in contact with each other and conductive with each other. In this case, a probe is desirably placed against the metal member 61 exposed from the laminate films 41. In the laminate-type electrical storage device 10, the potentials of the metal sheets 51 of the laminate films 41 are easy to detect due to the attachment of the metal member 61. As a result, the short-circuiting between the laminate films 41 and the positive electrode collection tab 22, and the short-circuiting between the laminate films 41 and the negative electrode collection tab 23 can be easily inspected.

Incidentally, as shown in FIGS. 1 and 3, the exterior body 40 of the laminate-type electrical storage device 10 may be constituted of the two laminate films 41. The two laminate films 41 may cover the electrode lamination portion 21 of the electrode body 20 in a sandwiching manner. In this case, the exterior body 40 may have the mating surface 41c obtained by fusing the thermoplastic resin layers 53 of the two laminate films 41 to each other, along the periphery of the electrode lamination portion 21. The laminate-type electrical storage device 10 has the metal exposure portion 60 for inspecting the potentials of the metal sheets 51 of the laminate films 41, at least partially outside the mating surface 41c around the electrode lamination portion 21, as described above. Due to the provision of the metal exposure portion 60, the short-circuiting between the two laminate films 41 of the exterior body 40 and the positive electrode collection tab 22, and the short-circuiting between the two laminate films 41 and the negative electrode collection tab 23 can be easily inspected.

A single electrical storage device module can be configured by accommodating a plurality of laminate-type electrical storage devices 10 in a predetermined case and appropriately combining the devices 10 with one another. In this case, a monitor unit that monitors the voltage and the temperature may be mounted for each module, or a charge/discharge circuit may be mounted for each module. This electrical storage device module is configured such that a predetermined voltage is output for each module, and can be mounted on a vehicle as, for example, a vehicle driving electric power supply for an electric vehicle. In this case, in the electrical storage device module, each of the laminate-type electrical storage devices 10 accommodated in the case may have the metal exposure portion 60 for inspecting the potentials of the metal sheets 51 of the laminate films 41 as described above. In this case, the electrical storage device module may be configured such that a short-circuiting failure of the laminate films 41 of each of the laminate-type electrical storage devices 10 is detected with each of the laminate-type electrical storage devices 10 assembled into the electrical storage device module.

Each of the laminate-type electrical storage devices 10 may have the metal exposure portion 60 for inspecting the potentials of the metal sheets 51 of the laminate films 41 as described above. It should be noted, however, that the metal exposure portion 60 may be cut and removed after being subjected to a required inspection.

For example, in the embodiment shown in FIG. 2, the regions 41b of the laminate films 41 extending outward from the mating surface 41c may be cut and removed after inspecting the short-circuiting between the laminate films 41 and the positive electrode collection tab 22, and the short-circuiting between the laminate films 41 and the negative electrode collection tab 23. In the embodiment shown in FIG. 3, the metal member 61 exposed from the laminate films 41 may be removed after the inspection.

The regions 41b of the laminate films 41 extending outward from the mating surface 41c may be entirely removed. Alternatively, only those parts of the regions 41b of the laminate films 41 extending outward from the mating surface 41c where the inside surfaces 51a of the metal sheets 51 are exposed respectively may be removed in particular. Since the metal exposure portion 60 has been removed after the inspection, the metal sheets 51 of the laminate films 41 can be prevented from becoming conductive with an external member through the parts where the inside surfaces 51a of the metal sheets 51 are exposed.

Besides, in a method of inspecting the short-circuiting of a laminate-type electrical storage device proposed in this specification, the laminate-type electrical storage device equipped with the metal exposure portion 60 as described above is first prepared. In the prepared laminate-type electrical storage device 10, the mating surface 41c obtained by heat-sealing the thermoplastic resin layers 53 of the laminate films 41 to each other exists around the electrode lamination portion 21. Besides, the positive electrode collection tab 22 and the negative electrode collection tab 23 stick out from the mating surface beyond the laminate films 41. There is a metal exposure portion for inspecting the potentials of metal sheets of the laminate films 41 at least partially outside the mating surface 41c.

Subsequently, a first probe of a resistance measuring device is placed against the metal exposure portion 60 of the laminate-type electrical storage device 10, and a second probe of the resistance measuring device is placed against the positive electrode collection tab 22 or the negative electrode collection tab 23. With this method of inspecting the short-circuiting of the laminate-type electrical storage device 10, the resistance between the first probe and the second probe is easily measured, and the short-circuiting between the laminate films 41 and the positive electrode collection tab 22, or the short-circuiting between the laminate films 41 and the negative electrode collection tab 23 is easily inspected.

The laminate-type electrical storage device disclosed in this specification, and the method of inspecting the short-circuiting of the laminate-type electrical storage device disclosed in this specification have been described above in various manners. The embodiments and the like of the laminate-type electrical storage device mentioned in this specification do not limit the disclosure, unless otherwise specified.

For example, as regards the electrode body 20, the shape of the electrode lamination portion 21, the positions where the positive electrode collection tab 22 and the negative electrode collection tab 23 extend from the electrode lamination portion 21, the positions where the positive electrode collection tab 22 and the negative electrode collection tab 23 stick out from the mating surface 41c of the two laminate films 41, and the like are not limited to those in the embodiments shown in FIGS. 1 and 3, but can be appropriately changed. The position where the metal exposure portion 60 is provided, and the like can also be appropriately changed.

FIG. 4 is a schematic view showing a laminate-type electrical storage device 10B according to still another one of the embodiments. In the laminate-type electrical storage device 10B, as shown in FIG. 4, a region 41c1 extending further outward is formed as part of the mating surface 41c of the laminate films 41. The metal member 61 as the metal exposure portion 60 is attached to the region 41c1. In the laminate-type electrical storage device 10B, after inspecting the short-circuiting of the laminate films 41, the unwanted region 41c1 of the laminate films 41 to which the metal member 61 is attached may be cut and removed.

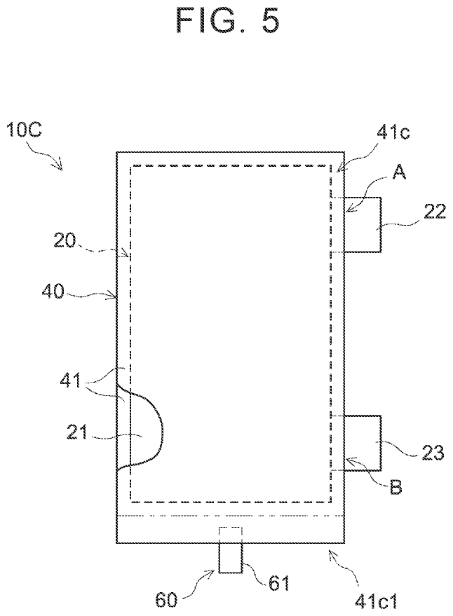

FIG. 5 is a schematic view showing a laminate-type electrical storage device 10C according to still another one of the embodiments. In the laminate-type electrical storage device 10C, as shown in FIG. 5, the positive electrode collection tab 22 and the negative electrode collection tab 23 are attached to the substantially rectangular electrode lamination portion 21 at two locations along one of long sides thereof. The positive electrode collection tab 22 and the negative electrode collection tab 23 stick out from the mating surface 41c, along one of long sides of each of the laminate films 41. The region 41c1 extending further outward from the mating surface 41c of the laminate films 41 is formed on the metal member 61 as the metal exposure portion 60, along the side of each of the laminate films 41 from which the positive electrode collection tab 22 and the negative electrode collection tab 23 do not stick out, namely, along one of short sides of each of the laminate films 41 in this case. Moreover, the metal member 61 as the metal exposure portion 60 is attached to the region 41c1.

In this manner, the positions where the positive electrode collection tab 22 and the negative electrode collection tab 23 stick out from the laminate films 41, the position where the metal exposure portion 60 is provided, and the like can be changed in various manners.

What is claimed is:

1. A laminate-type electrical storage device comprising:
an electrode body; and
an exterior body equipped with one or a plurality of laminate films, wherein
the electrode body has an electrode lamination portion, a positive electrode collection tab, and a negative electrode collection tab,
the laminate film or each of the laminate films has a metal sheet, an insulating resin layer that covers an outside surface of the metal sheet, and a thermoplastic resin layer that covers an inside surface of the metal sheet, and
the exterior body envelops the electrode lamination portion by the laminate film or the laminate films, has a mating surface obtained by superimposing portions of an inside surface of the laminate film or inside surfaces of the laminate films on each other and heat-sealing the thermoplastic resin layer to the inside surface or each of the inside surfaces, around the electrode lamination portion, ensures that the positive electrode collection tab and the negative electrode collection tab stick out from the mating surface beyond the laminate film or the laminate films, and has a metal exposure portion for inspecting a potential of the metal sheet of the laminate film or each of the laminate films, at least partially outside the mating surface around the electrode lamination portion.

2. The laminate-type electrical storage device according to claim 1, wherein
the laminate film or each of the laminate films has a region extending outward beyond the mating surface around the electrode lamination portion, and
the metal exposure portion has a part where the inside surface of the metal sheet is exposed, at least partially in the region extending outward beyond the mating surface.

3. The laminate-type electrical storage device according to claim 1, further comprising:
a metal member that is sandwiched between portions of the laminate film or between the laminate films, that is electrically connected to the metal sheet of the laminate film or each of the laminate films, and that is exposed from the laminate film or each of the laminate films, on the mating surface of the laminate film or the laminate films.

4. The laminate-type electrical storage device according to claim 1, wherein
the exterior body is constituted of two laminate films that cover the electrode lamination portion in a sandwiching manner, and has a mating surface obtained by fusing the thermoplastic resin layers of the two laminate films to each other, along a periphery of the electrode lamination portion.

5. A method of inspecting short-circuiting of a laminate-type electrical storage device, the method comprising:
a process of preparing the laminate-type electrical storage device according to claim 1; and
a process of placing a first probe against a part of the laminate-type electrical storage device where the inside surface of the metal sheet is exposed, and placing a second probe against the positive electrode collection tab or the negative electrode collection tab.
